(19) United States
(12) Patent Application Publication
(10) Pub. No.: US 2010/0120195 A1
(43) Pub. Date: May 13, 2010

(54) METHOD FOR MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/615,746

(22) Filed: Nov. 10, 2009

(30) Foreign Application Priority Data
Nov. 11, 2008 (KR) 10-2008-0111442

(51) Int. Cl. H01L 21/30; H01L 21/306

(52) U.S. Cl. 438/98; 156/345.1; 257/E21.211

(57) ABSTRACT

In a method for forming an image sensor, an interlayer dielectric may be formed over a semiconductor substrate. The interlayer dielectric may include an interconnection. A via hole may be formed through the interlayer dielectric by performing an etching process on the semiconductor substrate. The via hole exposes the interconnection. A first cleaning process and a second cleaning process may be performed on the semiconductor substrate including the via hole. The contact plug may be formed by filing a metal material in the via hole. The image sensing unit, with a first doping layer and a second doping layer stacked therein may be formed over the interlayer dielectric including the interconnection and the contact plug. Here, the first and second cleaning processes include removing residues formed over a sidewall of the via hole through the etching process.

The present application claims priority under 35 U.S.C. 119 to Korean Patent Application No. 10-2008-0111442 (filed on Nov. 11, 2008), which is hereby incorporated by reference in its entirety.

### BACKGROUND

Image sensors are semiconductor devices that convert optical images to electric signals. Image sensors are generally classified into charge coupled device (CCD) image sensors and complementary metal oxide silicon (CMOS) image sensors (CIS). The CIS includes a photodiode region for converting light signals to electrical signals, and a transistor region for processing the converted electrical signals. The photodiode region and the transistor region are horizontally arranged in a semiconductor substrate. In such a horizontal arrangement, the extent to which the optical sensing region is confined within a limited area is typically referred to as a “fill factor”.

To overcome fill factor limitations, attempts to form a photodiode using amorphous silicon (Si), or forming readout circuitry in the Si substrate using a method such as wafer-to-wafer bonding and forming a photodiode over the readout circuitry have been made (hereinafter, referred to as a “three-dimensional (3D) image sensor). The photodiode is connected with the readout circuitry through a metal line.

In this case, a via hole is formed in an interlayer dielectric to form a contact plug connected to the interconnection formed in the circuitry. However, residues formed on the sidewall of the via hole when the via hole is formed are not perfectly removed, resulting in a source of defects in the image sensor.

### SUMMARY

In embodiments, a method for manufacturing an image sensor includes an interlayer dielectric which may be formed over a semiconductor substrate. The interlayer dielectric may include an interconnection. A via hole may be formed through the interlayer dielectric by performing an etching process on the semiconductor substrate. The via hole exposes the interconnection. A first cleaning process and a second cleaning process may be performed on the semiconductor substrate including the via hole. The contact plug may be formed by filing a metal material in the via hole. The image sensing unit, with a first doping layer and a second doping layer stacked therein may be formed over the interlayer dielectric including the interconnection and the contact plug. Here, the first and second cleaning processes include removing residues formed over a sidewall of the via hole through the etching process.

### DRAWINGS

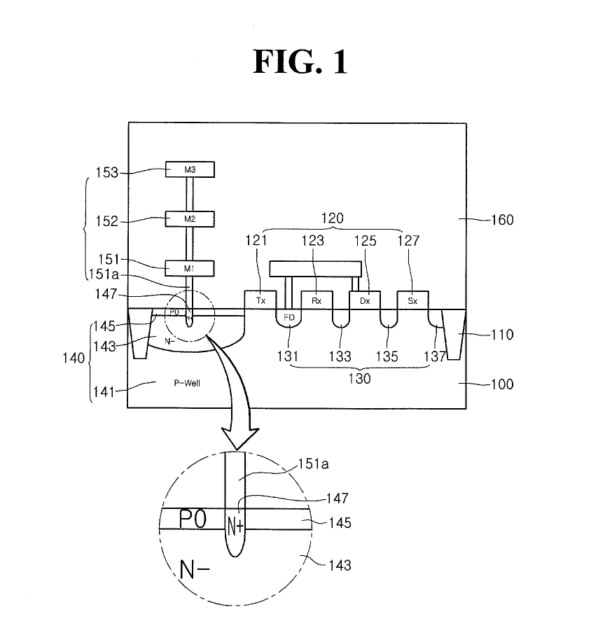

Example FIGS. 1 through 9 are side cross-sectional views illustrating a process for manufacturing an image sensor according to embodiments.

### DESCRIPTION

Hereinafter, a method for manufacturing an image sensor according to embodiments will be described in detail with reference to example FIGS. 1 through 9. Embodiments are not limited to CMOS image sensors, and may include any type of image sensor, such as a CCD image sensor, that require a photodiode.

Referring to example FIG. 1, an interconnection 150 and an interlayer dielectric 160 may be formed over the semiconductor substrate 100 including a readout circuit 120. The semiconductor substrate 100 may be a mono- or poly-crystalline silicon substrate, and may be doped with P-type impurities or N-type impurities. For example, a device isolation layer 110 may be formed in the semiconductor substrate 100 to define an active region. A readout circuit 120 including transistors for a unit pixel may be formed in the active region. For example, the readout circuit 120 may include a transfer transistor (Tx) 121, a reset transistor (Rx) 123, a drive transistor (Dx) 125, and a select transistor (Sx) 127. Thereafter, an ion implantation region 130 including a floating diffusion region (FD) 131 and source/drain regions 133, 135 and 137 for each transistor may be formed. The readout circuit 120 may also be applied to a 3Tr or 5Tr structure.

The forming of the readout circuitry 120 on the first substrate 100 may include forming an electrical junction region 140 on the first substrate 100 and forming a first conductivity type connection 147 connected to the connection 150 at an upper part of the electrical junction region 140.

For example, the electrical junction region 140 may be a P-N junction 140, but embodiments are not limited thereto. For example, the electrical junction region 140 may include a first conductivity type ion implantation layer 143 formed on a second conductive well 141 or a second conductive epitaxial layer, and a second conductivity type ion implantation layer 145 formed on the first conductivity type ion implantation layer 143. For example, as described in example FIG. 1, the P-N junction 140 may be a P0(145)/N−(143)/P−(141) junction, but embodiments are not limited thereto. The first substrate 100 may be a second conductivity type, but embodiments are not limited thereto.

According to embodiments, the device is designed to have a potential difference between the source and drain of the transfer transistor (Tx), thereby enabling the full dumping of a photo charge. Thus, photo charges generated in the photodiode may be dumped to a floating diffusion region, thereby increasing the output image sensitivity. That is, embodiments may form the electrical junction region 140 in the first substrate 100 including the readout circuit 120 to provide a potential difference between the source and drain of the transfer transistor (Tx) 121, thereby enabling the full dumping of the photo charges.

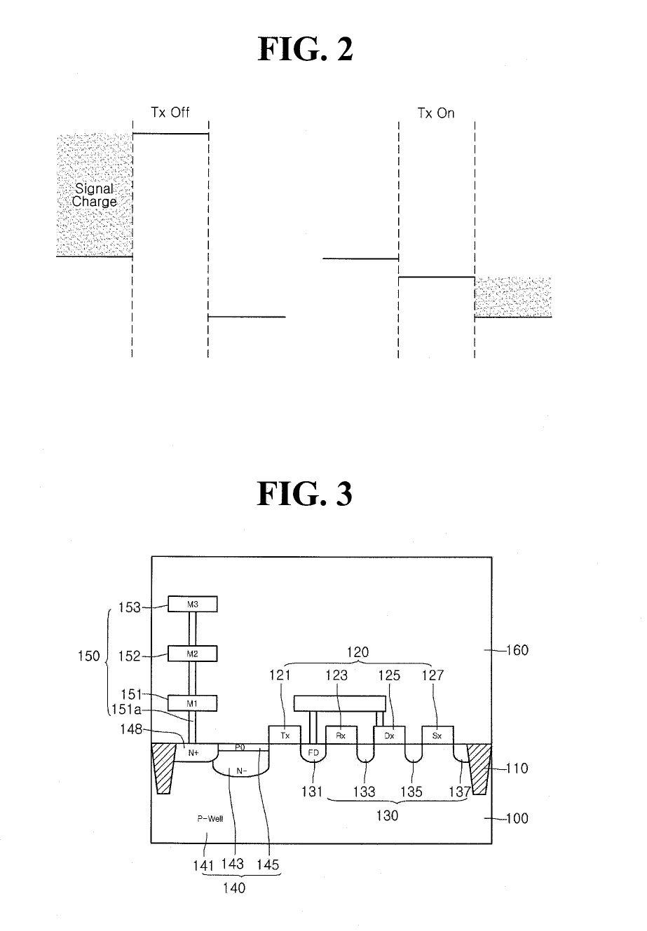

Hereinafter, a dumping structure of a photo charge according to embodiments will be described in detail with reference to example FIGS. 1 and 2. In embodiments, unlike a second floating diffusion (FD) 131 node of an N+ junction, the P/N/P junction 140 of the electrical junction region 140 may be pinched off at a predetermined voltage without an applied voltage being fully transferred thereto. This voltage is called a pinning voltage. The pinning voltage may depend on the P0 (145) and N− (143) doping concentration.

Specifically, electrons generated in the photodiode may be transferred to the PNP junction 140, and they may be transferred to the floating diffusion (FD) 131 node to be converted into a voltage when the transfer transistor (Tx) 121 is turned on.

The maximum voltage of the P0/N-/P-junction 140 becomes a pinning voltage, and the maximum voltage of the FD 131 node becomes Vdd minus the threshold voltage (Vth) of the reset transistor (Rx). As described in example FIG. 2, due to a potential difference between both ends of the Tx 121, without charge sharing, electrons generated in the photodiode at upper part of the chip can be completely dumped to the FD 131 node.

That is, in embodiments, a P0/N-/P-well junction instead of an N+/P-well junction may be formed in a silicon substrate (Si-Sub) of the semiconductor substrate 100. The reason for this is that, in a 4-Tr APS reset operation, a positive (+) voltage may be applied to the N− (143) in the P0/N-/P-well junction and a ground voltage may be applied to the P0 (145) and the P-well (141). Thus, a P0/N-/P-well double junction generates a pinch-off at a predetermined voltage or higher like in a BJT structure. This is called a pinning voltage. Thus, a potential difference occurs between the source and drain of the Tx 121, thus making it possible to prevent a charge sharing phenomenon due to full dumping of photocharges from N-well to FD through Tx in a Tx on/off operation. Accordingly, unlike a case where a photodiode is simply connected to an N+ junction in a related-art image sensor, embodiments can avoid saturation reduction and sensitivity degradation.

Thereafter, a first conductivity type connection 147 may be formed between the photodiode and the readout circuit to create a smooth transfer path of a photo charge, thereby making it possible to minimize a dark current source and prevent saturation reduction and sensitivity degradation. For this, embodiments may form an N+ doping region as a first conductivity type connection 147 for an ohmic contact on the surface of the P0/N-/P-junction 140. The N+ region 147 may be formed to contact N− 143 through the P0 (145).

On the other hand, the width of the first conductivity type connection 147 may be minimized to inhibit the first conductivity type connection 147 from becoming a leakage source. For this, in embodiments, a plug implant may be performed after etching of a second metal contact 151a, but embodiments are not limited thereto. For example, after an ion implantation pattern may be formed, the first conductivity type connection 147 may be formed using the ion implantation pattern as an ion implantation mask.

That is, the reason why an N+ doping is locally performed only on a contact formation region as described in embodiments is to minimize a dark signal and facilitate formation of an ohmic contact. If the entire Tx source region is N+ doped as in the related art, a dark signal may increase due to an Si surface dangling bond.

Example FIG. 3 illustrates another structure of a readout circuit. As described in example FIG. 3, a first conductivity type connection region 148 may be formed at one side of the electric junction region 140. Referring to example FIG. 3, an N+ connection region 148 may be formed at a P0/N-/P-junction 140 for an ohmic contact. In this case, a leakage source may be generated during the formation process of an N+ connection region 148 and a M1C contact 151a. This is because an electric field (EF) may be generated over the Si surface during operation while a reverse bias is applied to P0/N-/P-junction 140. A crystal defect generated during the contact formation process inside the electric field may become a leakage source.

Also, when the N+ connection region 148 is formed over the surface of P0/N-/P-junction 140, an electric field may be additionally generated due to N+/P0 junction 148/145. This electric field may also become a leakage source. That is, embodiments propose a layout in which first contact plug 151 a may be formed in an active region not doped with a P0 layer but including N+ connection region 148 and may be connected to N-junction 143. Then, the electric field is not generated over the surface of the semiconductor substrate 100, which can contribute to reduction of a dark current of a 3D integrated CIS.

Referring again to example FIG. 1, an interlayer dielectric 160 and an interconnection 150 may be formed over the semiconductor substrate 100. The interconnection 150 may include a second metal contact 151a, a first metal (M1) 151, a second metal (M2) 152, and a third metal (M3) 153, but embodiments are not limited thereto. In embodiments, after formation of the third metal 153, a dielectric layer may be formed to cover the third metal 153, and a planarization process may be performed to form the interlayer dielectric 160. Thus, the surface of the interlayer dielectric 160, having a uniform surface profile, may be exposed on the semiconductor substrate 100.

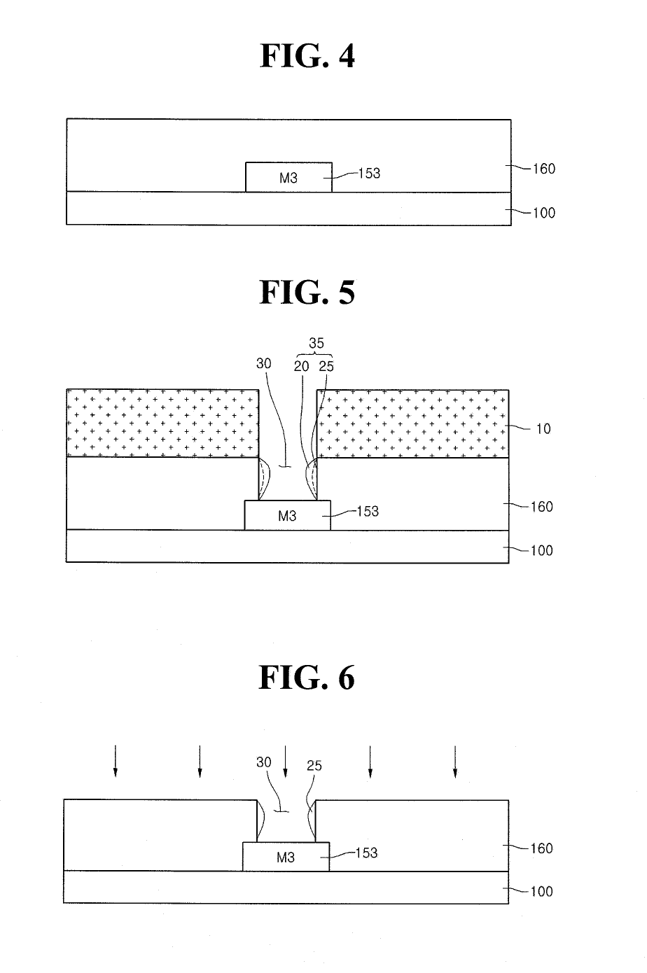

The third metal 153 and the interlayer dielectric 160 shown in example FIG. 4 are portions of the interconnection 150 and the interlayer insulating layer 160 shown in example FIG. 1. For convenience of explanation, portions of the readout circuitry 120 and the interconnection 150 are omitted.

Next, referring to example FIG. 5, after a photoresist pattern 10 is formed over the interlayer dielectric 160, an etching process may be performed to form a via hole 30 exposing the third metal 153. In the etching process for forming the via hole 30, residues 35 such as polymers may be formed during formation of the via hole 30 to inhibit an etching on the sidewall of the via hole 30.

In particular, the residues 35 may be formed of a first residue 35 and a second residue 20. The second residue 20 may be exposed to the outside, and become hard, while the first residue 25 may be softer than the second residue 20, and be formed between the second residue and the sidewall of the via hole 30. Since it may be difficult to remove the first residue 25 and the second residue 20 at the same time, the residues 35 can be completely removed through a second cleaning process in embodiments.

As shown in example FIG. 6, a first cleaning process may be performed on the semiconductor substrate to remove the second residue 20 from the sidewall of the via hole 30. The first cleaning process may be performed using Deionized Water (DIW) at a temperature of about 70° C. to about 90° C. for about 5 minutes to about 20 minutes.

The second residue 20 is exposed to the outside, and thus is formed hard. However, if the inside of the via hole 30 is processed using activated DIW at a temperature of about 70° C. to about 90° C., the hard second residue 20 over the surface of the residues, which may include polymers, can be dissolved and removed.

If a spin method is used in the process using the DIW, the DIW is injected while the semiconductor substrate 100 is rotated at a speed of about 200 rpm to about 800 rpm. If a Quick Dump Drain (QDR) method is used instead of the spin method, then the DIW processing may be performed for about 1 minute to about 30 minutes, and the semiconductor substrate 100 may be dried using N₂.

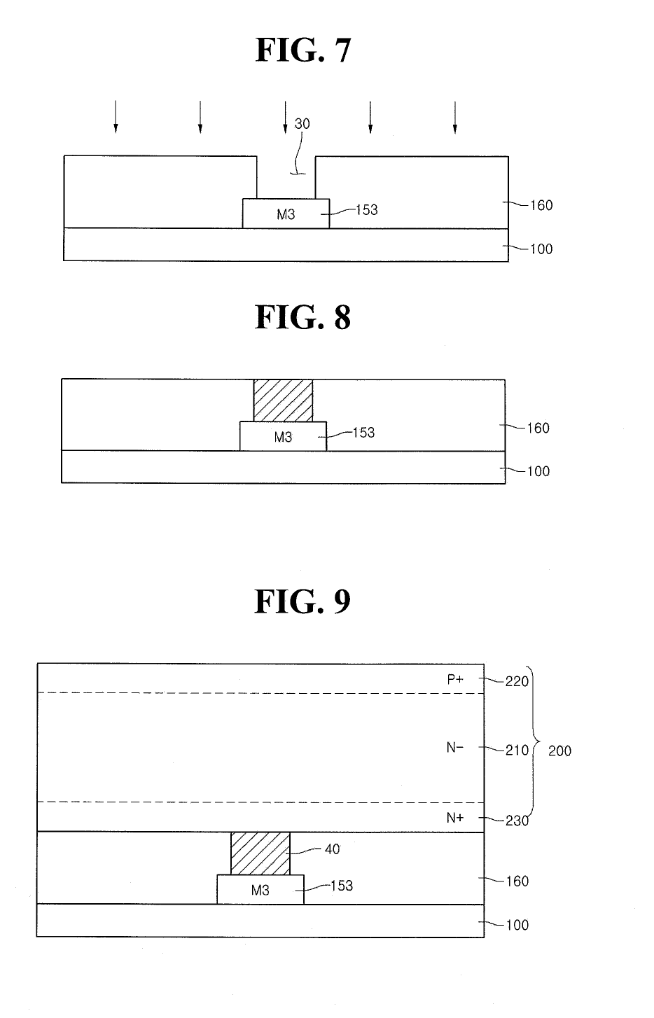

Next, referring to example FIG. 7, the second cleaning process may be performed on the semiconductor substrate 100 to remove the first residue left over the sidewall of the via hole 30. The second cleaning process may be performed using a basic solution including NH₄F chemicals.

After the first and second cleaning processes are performed, a process for drying the semiconductor substrate 100 may be performed through an N₂ processing step, while the semiconductor substrate 100 is rotated at a speed of about 1,000 rpm to about 2,000 rpm for about 1 minute to about 30 minutes

After an exposed portion of the residues 35 over the sidewall of the via hole 30 is removed through the first cleaning process using DIW, the remaining first residue 25 may be removed through the second cleaning process using a basic solution including NH₄F chemicals. Thus, all the residues 35 such as polymers which may be generated in the forming of the via hole 30 are removed, thereby preventing the characteristics of the device from being degraded by the residues 35.

Referring to example FIG. 8, a metal material may be filled to form a contact plug 40 in the via hole 30 after the removal of the residue 35. Next, referring to example FIG. 9, an image sensing unit 200 may be formed over the interlayer dielectric 160. The image sensing unit 200 may have a PN junction photodiode structure including a first doping layer (N−) 210 and a second doping layer (P+) 220.

For example, the image sensing unit 200 may be formed in a stacked structure of the first doping layer 210 and the second doping layer 220 by ion-implanting N-type impurities (N−) and P-type impurities (P+) in succession into a crystalline P-type carrier substrate. In addition, high-concentration N-type impurities (N+) may be ion-implanted under the first doping layer 210 to form the ohmic contact layer 230. The ohmic contact layer 230 may reduce the contact resistance between the image sensing unit 200 and the interconnection 150.

In embodiments, the first doping layer 210 may be formed in a broader region than the second doping layer 220. Then, the depletion region thereof may be expanded to increase the generation of photoelectrons.

Next, after disposing the ohmic contact layer 230 of the carrier substrate over the dielectric interlayer 160, a bonding process may be performed to bond the semiconductor substrate 100 and the carrier substrate. Then, the carrier substrate, having a hydrogen layer therein, may be removed through a cleaving process to expose the image sensing unit 200 bonded to the interlayer dielectric 160. For example, the height of the image sensing unit 200 may range from about 1.0 μm to about 1.5 μm. That is, since the semiconductor substrate 100, where the readout circuitry 120 is formed, and the image sensing unit 200 are formed through a wafer-to-wafer bonding, generation of a defect can be inhibited.

The image sensing unit 200 may be disposed over the readout circuit 120, thereby increasing a fill factor. Also, the image sensing unit 200 may be bonded to the surface of the interlayer dielectric 160 having a uniform surface profile, thereby increasing the bonding strength physically.

Although the image sensing unit may be formed to have a PN junction, the image sensing unit may also be formed to have a PIN junction. Also, after an interlayer isolation layer is formed through an etching process that separates the image sensing unit 200 into unit pixels, an upper electrode, a color filter, and a microlens are additionally formed over the image sensing unit 200.

In a method for manufacturing an image sensor according to embodiments, after an exposed portion of the residues over the sidewall of the via hole is removed through the first cleaning process using DIW, the remaining first residue is removed through the second cleaning process using a basic solution including NH₄F chemicals. Thus, all the residues such as polymers generated in the forming of the via hole may be removed, thereby preventing the characteristics of the device from being degraded by the residues.

In addition, according to embodiments, the device may be designed to provide a potential difference between the source and drain of the transfer transistor (Tx), thereby enabling the full dumping of a photo charge. Also, according to embodiments, the conductive connection can be formed between the photodiode and the readout circuit to create a smooth transfer path of a photo charge, thereby making it possible to minimize a dark current source and inhibit saturation reduction and sensitivity degradation.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an interlayer dielectric over a semiconductor substrate, the interlayer dielectric including an interconnection;
forming a via hole through the interlayer dielectric by performing an etching process on the semiconductor substrate, the via hole exposing the interconnection;
performing a first cleaning process and a second cleaning process on the semiconductor substrate including the via hole;
forming a contact plug by filling in the via hole with a metal material; and
forming an image sensing unit over the interlayer dielectric including the interconnection and the contact plug,
wherein the first and second cleaning processes include removing residues formed over a sidewall of the via hole through the etching process.

2. The method of claim 1, wherein the first cleaning process includes removing an exposed residue from the residues formed over the sidewall of the via hole through the etching process.

3. The method of claim 1, wherein the second cleaning process includes removing a remaining residue after the first cleaning process.

4. The method of claim 1, wherein the first cleaning process is performed using deionized water.

5. The method of claim 4, wherein the first cleaning process includes injecting the deionized water using a spin method.

6. The method of claim 5, wherein the spin method includes rotating the semiconductor substrate at a speed of about 200 rpm to about 800 rpm.

7. The method of claim 1, wherein the first cleaning process is performed at a temperature of about 70° C. to about 90° C.

8. The method of claim 1, wherein the first cleaning process is performed for about 5 minutes to about 20 minutes.

9. The method of claim 1, wherein the second cleaning process is performed using a basic solution including NH₄F chemicals.

10. The method of claim 1, including drying the semiconductor substrate through an N₂ processing after the performing of the first cleaning process and the second cleaning process.

11. The method of claim 10, wherein the drying of the semiconductor substrate includes rotating the semiconductor substrate at a speed of about 1,000 rpm to about 2,000 rpm for about 1 minute to about 30 minutes.

12. The method of claim 1, wherein forming an image sensing unit includes forming an image sensing unit having a first doping layer and a second doping layer stacked therein.

13. A apparatus configured to:
form an interlayer dielectric over a semiconductor substrate, the interlayer dielectric including an interconnection;
form a via hole through the interlayer dielectric by performing an etching process on the semiconductor substrate, the via hole exposing the interconnection;
perform a first cleaning process and a second cleaning process on the semiconductor substrate including the via hole;
form a contact plug by filling in the via hole with a metal material; and
form an image sensing unit over the interlayer dielectric including the interconnection and the contact plug,
wherein the first and second cleaning processes remove residues formed over a sidewall of the via hole through the etching process.

14. The apparatus of claim 13, configured to remove an exposed residue from the residues formed over the sidewall of the via hole through the etching process in the first cleaning process.

15. The apparatus of claim 13, configured to remove a remaining residue after the first cleaning process during the second cleaning process.

16. The apparatus of claim 13, configured to perform the first cleaning process using deionized water.

17. The apparatus of claim 16, configured to inject the deionized water using a spin method during the first cleaning process.

18. The apparatus of claim 17, configured to rotate the semiconductor substrate at a speed of about 200 rpm to about 800 rpm during the first cleaning process.

19. The apparatus of claim 13, configured to perform the first cleaning process at a temperature of about 70° C. to about 90° C.

20. The apparatus of claim 13, configured to perform the second cleaning process using a basic solution including NH₄F chemicals.
